(19) United States
(12) Patent Application Publication
(10) Pub. No.: US 2016/0380642 A1
(43) Pub. Date: Dec. 29, 2016

(54) DIVISOR CONTROL CIRCUIT, FRACTIONAL FREQUENCY DIVISION DEVICE, FREQUENCY SYNTHESIZER AND FREQUENCY SYNTHESIS METHOD

(71) Applicant: MEDIATEK SINGAPORE PTE. LTD., Singapore (SG)

(72) Inventor: Min-Jie Wu, Singapore (SG)

(21) Appl. No.: 15/125,146

(22) PCT Filed: Mar. 12, 2015
(86) PCT No.: PCT/CN2015/074123

§ 371 Date: Sep. 10, 2016

Related U.S. Application Data
(60) Provisional application No. 61/951,709, filed on Mar. 12, 2014.

(51) Int. Cl. H03L 7/197; H03K 19/20

(52) U.S. Cl. CPC H03L 7/1974; H03K 19/20

(57) ABSTRACT

A divisor control circuit allows a frequency divider to have a fractional divisor. The divisor control circuit includes: a multiplexer, arranged to select one of a first clock signal and a second clock signal as a multiplexed signal according to a selection signal, and accordingly provide the multiplexed signal to the frequency divider, wherein there is a phase difference between the first clock signal and the second clock signal; and a selection signal generation circuit, coupled to the multiplexer, arranged to generate the selection signal according to a frequency-divided signal outputted by the frequency divider. The multiplexer alternately selects the first clock signal and the second clock signal as the multiplexed signal during a period of the frequency-divided signal.

### CROSS REFERENCE TO RELATED APPLICATIONS

The present invention claims priority to U.S. Provisional Patent Application, Ser. No. 61/951,709, filed on Mar. 12, 2014. The U.S. Provisional Patent Applications are hereby incorporated by reference in their entireties.

### TECHNICAL FIELD

The present invention relates generally to frequency synthesis, and more particularly, to a divisor control circuit, a fractional frequency division device, a frequency synthesizer, and a frequency synthesis method for realizing a true fractional frequency division based on an integer frequency divider.

### BACKGROUND

Many current wireless communication systems such as Global System for Mobile Communications (GSM), 3rd-Generation (3G), Long term evolution (LTE), Wi-Fi, Global Positioning System (GPS), Bluetooth, and FM broadcasting are integrated into a single chip. Transceivers of the wireless systems in the chip need clock signals to operate, and different wireless systems require clock signals of different frequencies. These wireless systems may share a single frequency reference oscillator, however, due to cost considerations. With frequency synthesis techniques such as frequency multiplication and frequency division, the oscillator is able to provide signals having a wide range of frequencies for transceivers of different wireless systems, even though the oscillator produces a narrower range of frequencies.

FIG. 1 illustrates how to use an oscillator and a frequency divider to produce signals having specific frequencies. Suppose that a transceiver of a specific wireless system requires signals having frequencies from 795.1 MHz to 2062.2 MHz. Implementing a frequency divider after the oscillator, wherein the oscillator produces signal of a frequency that is a multiple of the frequency required by the transceiver, enables the frequency divider to divide the signal generated by the oscillator to produce the frequency required by the transceiver. Specifically, the oscillator can be configured to produce signals having frequencies from 3180.3 MHz to 3848.1 MHz. A divisor of the frequency divider is configured to 4, which enables production of signals having frequencies from 795.1 MHz to 962.0 MHz. In the same manner, when signals having frequencies from 1058.2 MHz to 1280.5 MHz are required, the oscillator can produce signals having frequencies from 3174.7 MHz to 3841.4 MHz and the divisor can be configured to 3; when signals having frequencies from 1408.5 MHz to 2062.2 MHz are required, the oscillator can produce signals having frequencies from 2817.0 MHz to 4124.4 MHz and the divisor of the frequency divider can be configured to 2. With the above-mentioned technique, the oscillator can produce signals with a frequency range from 2817.0 MHz to 4124.2 MHz.

If it is desirable to operate another wireless system simultaneously, the output frequency range from 2817.0 MHz to 4124.2 MHz of the oscillator needs to be reserved; otherwise, the operations of different wireless systems could negatively affect each other, causing malfunction. As more and more wireless systems are integrated together, however, more and more output frequency ranges of the oscillator are occupied. Therefore, there is a need to provide a method that can effectively reduce a frequency range of the oscillator that is occupied by one wireless system.

### SUMMARY

The present invention provides a divisor adjustment technique to map a wider frequency range required by the wireless system to a narrower output frequency range of the oscillator. To achieve the divisor adjustment technique, the present invention provides a divisor control for allowing a true fractional frequency division to be performed by an integer frequency divider, which makes the divisor of the frequency division adjustable in fractional steps.

According to one embodiment of the present invention, a divisor control circuit is provided. The divisor control circuit is employed for allowing a frequency divider to have a fractional divisor. The divisor control circuit comprises: a multiplexer and a selection signal generation circuit. The multiplexer is arranged to select one of a first clock signal and a second clock signal as a multiplexed signal according to a selection signal, and accordingly provide the multiplexed signal to the frequency divider, wherein there is a phase difference between the first clock signal and the second clock signal. The selection signal generation circuit is coupled to the multiplexer, and arranged to generate the selection signal according to a frequency-divided signal output by the frequency divider. Additionally, the multiplexer alternately selects the first clock signal and the second clock signal as the multiplexed signal during a period of the frequency-divided signal.

According to another embodiment of the present invention, a frequency division device is provided. The frequency division device comprises: a multiplexer, a frequency divider and a selection signal generation circuit. The multiplexer is arranged to select one of a first clock signal and a second clock signal as a multiplexed signal according to a selection signal, wherein there is a phase difference between the first clock signal and the second clock signal. The frequency divider is coupled to the multiplexer, and arranged to generate a frequency-divided signal according to the multiplexed signal. The selection signal generation circuit is coupled to the multiplexer, and arranged to provide the selection signal according to the frequency-divided signal. Additionally, the multiplexer alternately selects the first clock signal and the second clock signal as the multiplexed signal during a period of the frequency-divided signal.

According to still another embodiment of the present invention, a frequency synthesizer is provided. The frequency synthesizer comprises: an oscillator, a multiplexer, a frequency divider and a selection signal generation circuit. The oscillator is arranged to generate at least a first clock signal. The multiplexer is arranged to select one of the first clock signal and a second clock signal as a multiplexed signal according to a selection signal, wherein there is a phase difference between the first clock signal and the second clock signal. The frequency divider is coupled to the multiplexer, and arranged to generate a frequency-divided signal according to the multiplexed signal. The selection signal generation circuit is coupled to the multiplexer, and arranged to provide the selection signal according to the frequency-divided signal. Additionally, the multiplexer alternately selects the first clock signal and the second clock signal as the multiplexed signal during a period of the frequency-divided signal.

According to yet another embodiment of the present invention, a frequency synthesizing method is provided. The frequency synthesizing method comprises: providing a first clock signal and a second clock signal, wherein there is a phase difference between the first clock signal and the second clock signal; selecting the first clock signal and providing the first clock signal to the frequency divider for generating a first part of a frequency-divided signal according to the first clock signal; and in response to the frequency-divided signal, selecting the second clock signal and providing the second clock signal to the frequency divider for generating a second part of the frequency-divided signal according to the second clock signal.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIG. 1 illustrates how the conventional art uses an oscillator and a frequency divider to meet a frequency requirement of a wireless system.

FIG. 2 illustrates how the present invention uses an oscillator and a frequency division device to meet a frequency requirement of a wireless system.

FIG. 3 is a schematic diagram of a divisor control circuit and a frequency division device according to one exemplary embodiment of the present invention.

FIG. 4A is a timing diagram of an input clock signal and a frequency-divided signal.

FIG. 4B is a timing diagram of a first input clock signal, a second input clock signal and a frequency-divided signal.

FIG. 5A is a circuit diagram of a glitch-free multiplexer applicable to the divisor control circuit of FIG. 3.

FIG. 5B is a timing diagram of signals regarding the glitch-free multiplexer FIG. 5B.

FIG. 6 is a block diagram of a divisor control circuit and a frequency division device according to another exemplary embodiment of the present invention.

FIG. 7 is a flowchart of a frequency synthesis method according to one exemplary embodiment of the present invention.

### DETAILED DESCRIPTION

Certain terms are used throughout the following descriptions and claims to refer to particular system components. As one skilled in the art will appreciate, manufacturers may refer to a component by different names. This document does not intend to distinguish between components that differ in name but not differ in functionality. In the following discussion and in the claims, the terms “include”, “including”, “comprise”, and “comprising” are used in an open-ended fashion, and thus should be interpreted to mean “including, but not limited to . . . ” The terms “couple” and “coupled” are intended to mean either an indirect or a direct electrical connection. Thus, if a first device couples to a second device, that connection may be through a direct electrical connection, or through an indirect electrical connection via other devices and connections.

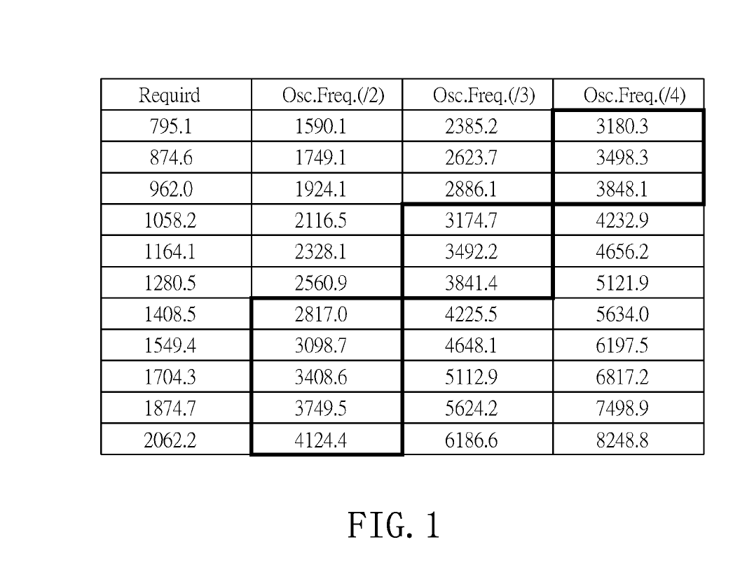

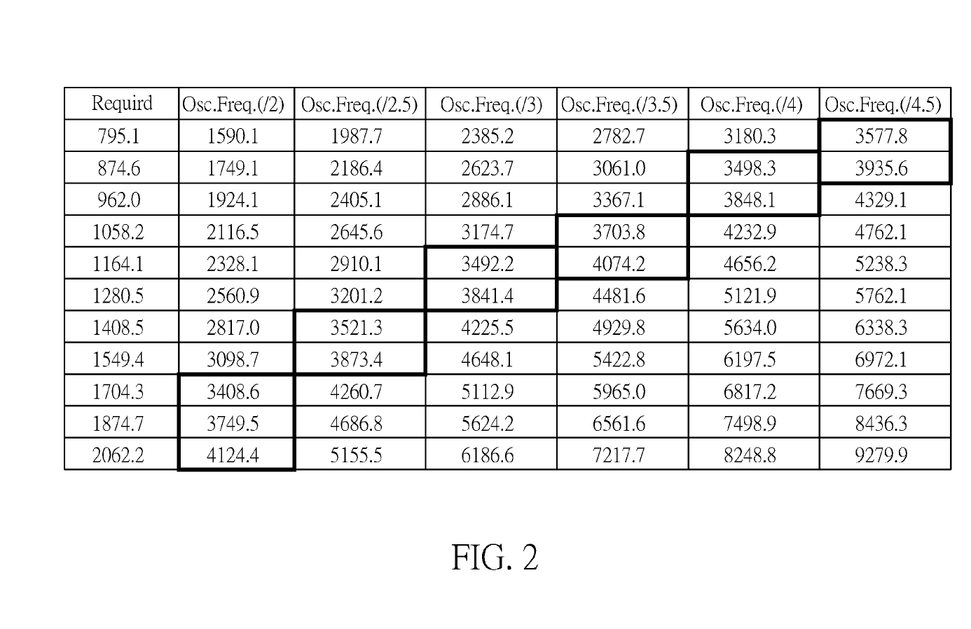

Please refer to FIG. 2, which illustrates how the present invention reduces an output frequency range of an oscillator that is occupied by a wireless system. As shown in the diagram, the wireless system originally requires signals having frequencies from 795.1 MHz to 2062.2 MHz (as in the case shown in FIG. 1). By adjusting a divisor of the frequency division device subsequent to the oscillator in steps of 0.5 (i.e. 2, 2.5, 3, 3.5, 4, 4.5), the oscillator only needs to produce signals having frequencies from 3408.6 MHz to 4124.4 MHz to meet the requirement of frequencies in a range from 791.5 MHz to 2062.2 MHz. With this technique, the wireless system only occupies about 700 MHz of the output frequency range of the oscillator, which is largely reduced from the frequency range occupied by the wireless system in FIG. 1.

According to one exemplary embodiment of the present invention, a frequency division device and a divisor control circuit is provided. The divisor control circuit is operable to make an integer frequency divider realize a fractional frequency division, and make a divisor of the frequency division adjustable in fractional steps. In the present invention, the frequency division device is operable to perform either a fractional frequency division or integer frequency division under the control of the divisor control circuit.

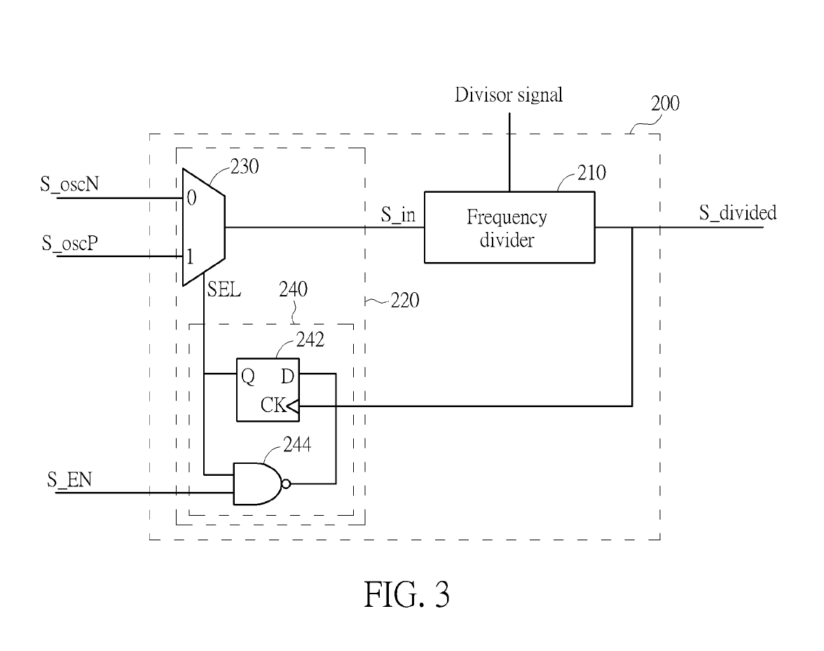

Please refer to FIG. 3, which illustrates a schematic diagram of a frequency division device and a divisor control circuit according to one exemplary embodiment of the present invention. As shown in FIG. 3, a frequency division device 200 includes a frequency divider 210 and a divisor control circuit 220. The frequency divider 210 is able to perform integer frequency division upon an input signal S_in. The divisor control circuit 220 is able to provide the input signal S_in to the frequency divider 210 by selecting one of a clock signal S_oscN and a clock signal S_oscP having the same frequency but different phases. The operation of the divisor control circuit 220 is controlled by an enablement signal S_EN. Depending on the enablement signal S_EN, the divisor control circuit 220 can either fixedly provide a same clock signal to the frequency divider 210 or alternately provide clock signals S_oscN and S_oscP to the frequency divider 210.

The divisor control circuit 220 further comprises a multiplexer 230 and a selection signal generation circuit 240. The multiplexer 230 determines which clock signal is selected as an output, and provides the clock signal to the frequency divider 210. The multiplexer 230 operates according to a selection signal SEL generated by the selection signal generation circuit 240.

In the case where the divisor control circuit 220 fixedly provides a same clock signal to the frequency divider 210, the frequency divider 210 divides the frequency of the input signal S_in by an integer divisor determined by a divisor signal, thereby generating a frequency-divided signal S_divided. The frequency division device 200 therefore realizes an integer frequency division. In the case where the divisor control circuit 220 alternately provides the clock signal S_oscN and the clock signal S_oscP to the frequency divider 210, the frequency divider 210 still operates like an integer frequency divider, but the frequency division device 200 actually produces the frequency-divided signal S_divided having a frequency which is a fractional (i.e. non-integer) multiple of the frequency of the input signal S_in.

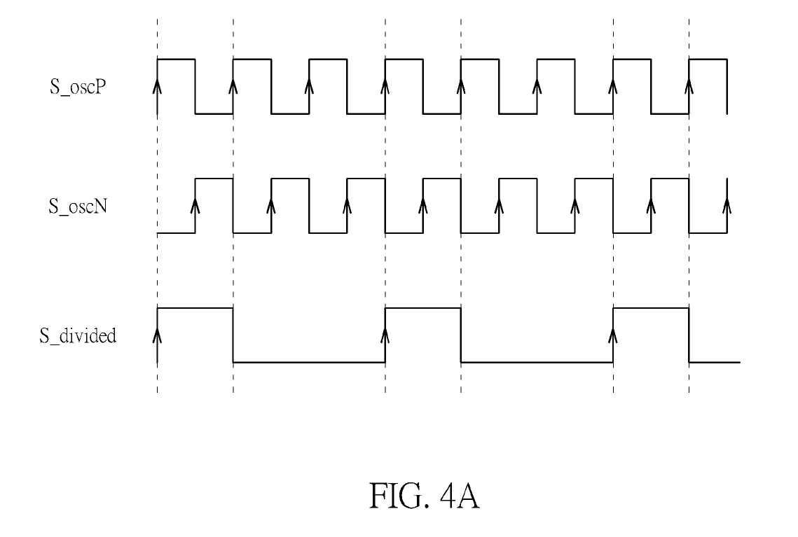

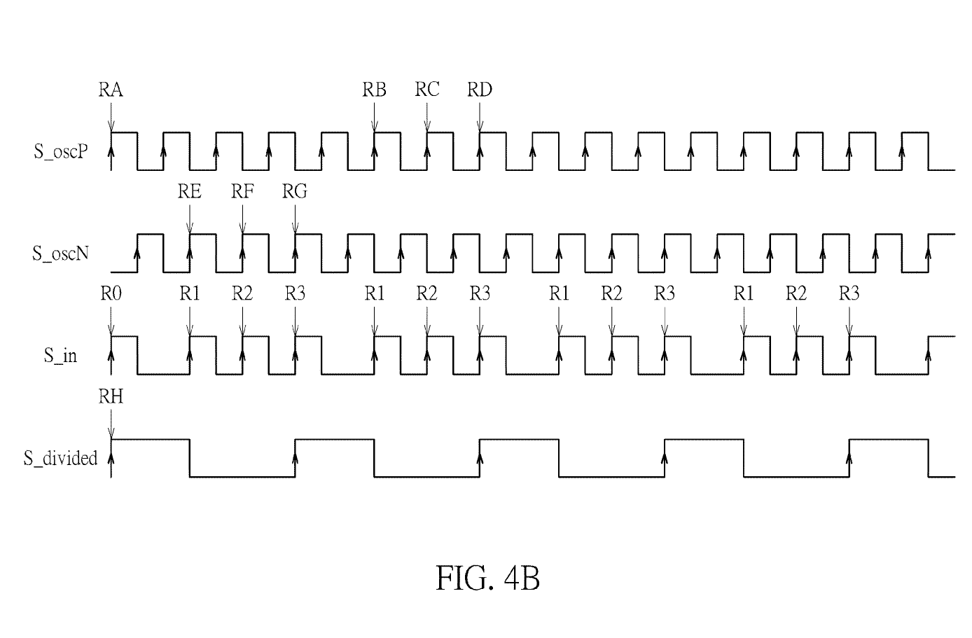

Please refer to FIG. 3 in conjunction with FIG. 4A. FIG. 4A illustrates a timing diagram of the frequency-divided signal S_divided and the selected clock signal in the case where the divisor control circuit 220 fixedly provides the clock signal S_oscP to the frequency divider 210. Certain rising edges of the clock signal S_oscP trigger the frequency divider 210 to transition the level of the frequency-divided signal S_divided. Therefore, the frequency of the clock signal S_oscP is an integral multiple of the frequency of the frequency-divided signal S_divided. In such a case, the level of the enablement signal S_EN (as an input of the NAND gate 244) needs to be configured as logic “0”. The output of the NAND gate 244 will be always logic “1” no matter how another input changes. The selection signal SEL generated by the selection signal generation circuit 240 can thereby make the multiplexer 230 fixedly select one of the clock signals.

Please refer to FIG. 3 in conjunction with FIG. 4B. FIG. 4B illustrates a timing diagram of the frequency-divided signal S_divided and the clock signals S_oscN and S_oscP in the case where the divisor control circuit 220 alternately provides the clock signals S_oscN and S_oscP to the frequency divider 210. A phase difference between clock signals S_oscN and S_oscP is assumed to be 180 degrees, and the level of the enablement signal S_EN is configured as logic “1”. The NAND gate 244 changes its output level whenever another input changes. In addition, the output level of the NAND gate 244 will be captured by the D-type flip-flop 242 and passed back to the NAND gate 244 as long as the D-type flip-flop 242 is trigged by edges of the frequency-divided signal S_divided. The level of the selection signal SEL will alternate during a period of the frequency-divided signal S_divided. The detailed operations will be described as below.

At first, assuming the D-type flip-flop 242 starts with logic “1” at its output, (i.e., the selection signal SEL is initially logic “1”), allowing the multiplexer 230 to select the clock signal S_oscP and to provide it to the frequency divider 210, the frequency divider 210 will be triggered by a rising edge RA of the clock signal S_oscP to have the frequency divided signal S_divided positively transitioned. Accordingly, as the NAND gate 244 receives two logic “1” (S_EN and SEL), its output should be logic “0”. Therefore, an input of the D-type flip-flop 242 captures logic “0”, and the output of the D-type flip-flop 242 changes from logic “1” to logic “0” on the rising edge of the frequency-divided signal S_divided. The selection signal SEL becomes logic “0”, and the multiplexer 230 selects the clock signal S_oscN as its output and provides it to the frequency divider 210.

In the case where the frequency divider 210 is configured to perform divide-by-3 division, the frequency divider 210 is assumed to positively transition the level of the frequency-divided signal S_divided each time the frequency divider 210 counts three rising edges from its input signal S_in after one rising edge of the frequency-divided signal S_divided. Hence, when the frequency divider 210 counts the rising edges R1, R2 and R3 of the input signal S_IN after the rising edge RH of the frequency divided signal S_divided, the frequency divider 210 again has the level of the frequency-divided signal S_divided positively transitioned on the rising edge R3 of its input signal S_IN (where the frequency-divided signal S_divided is negatively transitioned on the rising edge R1 of the input signal S_IN).

Positive transition of the frequency-divided signal S_divided will cause the selection signal SEL to be switched. On the rising edge RD of the clock signal S_oscN, the selection signal SEL is switched. Then, the multiplexer 230 again provides the clock signal S_oscP to the frequency divider 210. Afterward, the frequency divider 210 again counts another three rising edges R1-R3 of the clock signal S_IN (which follows the rising edges RE, RF and RG of the clock signal S_oscP now) and then positively transitions the frequency-divided signal S_divided to have the selection signal SEL switched again, thereby providing the clock signal S_oscN to the frequency divider 210. Please note that the design of the frequency division device of the present invention does not limit to using rising edge triggered logics. According to various embodiment of the present invention, using falling edge triggered logics can be available and also perform the same function like the above-mentioned embodiments.

Through the help of the divisor control circuit 230, a divide-by-3.5 frequency division can be achieved even though the frequency divider 210 actually performs a divide-by-3 frequency division. When the enablement signal S_EN is logic “0”, the frequency division device 200 can realize integer frequency division, and when the enablement signal S_EN is logic “1”, the frequency division device 200 can realize the fractional frequency division. In addition, by properly configuring integer divisors of the frequency divider 210 and the enablement signal S_EN, the frequency division device 200 is able to adjust the divisor in steps of 0.5. For example, when the enablement signal S_EN is logic “0”, and the integer divisor of the frequency division device 210 is configured to 3, the frequency division device 200 can produce a frequency division result of divide-by-3. When the enablement signal S_EN is logic “1”, and the integer divisor of the frequency division device 210 is configured to 3, the frequency division device 200 can produce a frequency division result of divide-by-3.5.

In the above embodiment, the selection signal generation circuit 240 is described as having the D-type flip-flop 242 and the NAND gate 244. This is not a limitation of the present invention, however. According to the various embodiments, the D-type flip-flop 242 could be replaced with other types of flip-flops or circuits as long as they can periodically sample a value at its input and hold the sampled value for an interval. In addition, the NAND gate 244 can also be replaced with one or a combination of several logic gates as long as they can always change their output when one of the inputs is fixed to a same value and the output is fed back to its other input. For example, the NAND gate 244 could be replaced with a NOR gate. If the NAND gate is replaced with the NOR gate, the multiplexer 230 can alternately provide the clock signals to the frequency divider 210 by means of configuring the enablement signal S_EN as logic “0”.

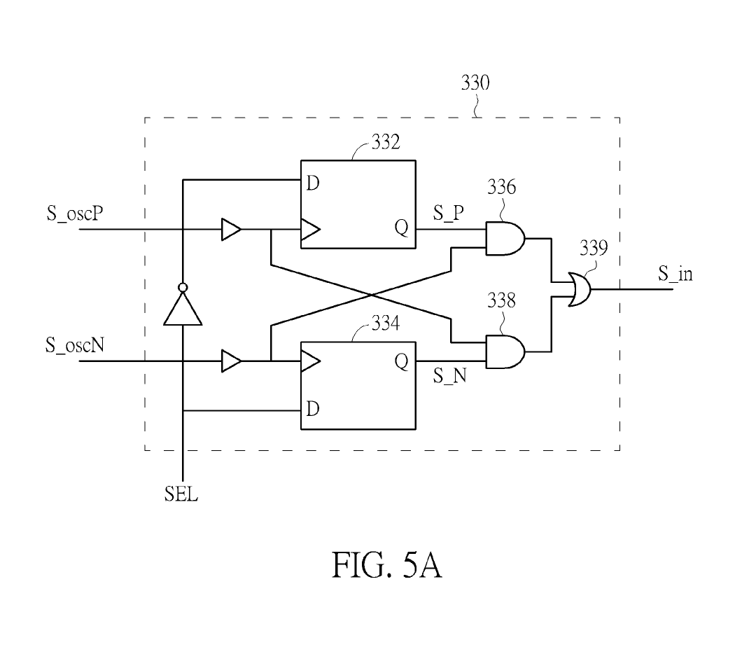

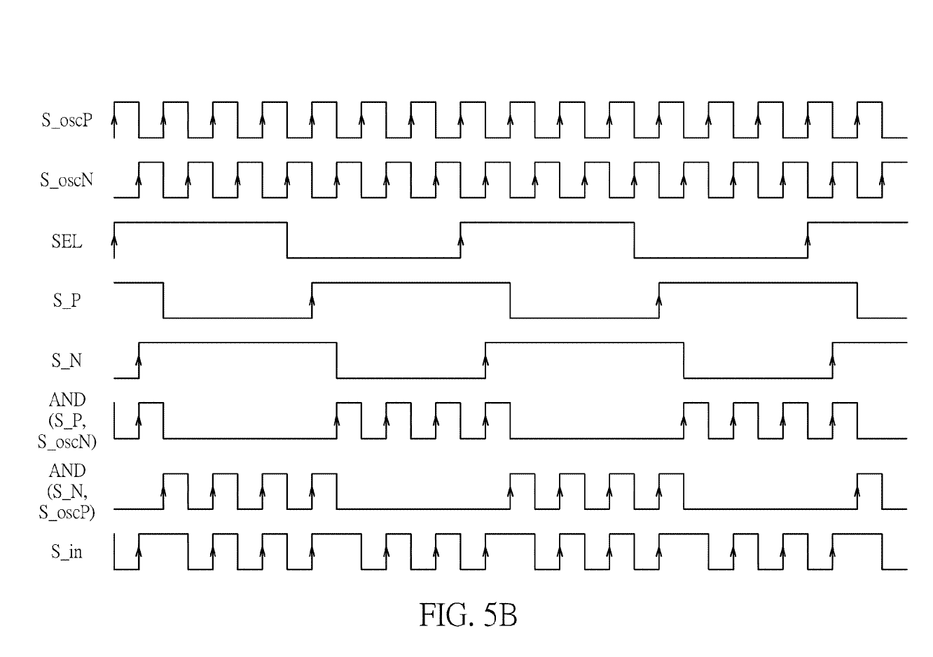

To prevent possible glitches in the input signal S_in of the frequency divider 210, the present invention further provides a glitch-free multiplexer, which is illustrated in FIG. 5A. The glitch-free multiplexer 330 receives the clock signals S_oscP and S_oscN, and selects one of them as an output in response to the selection signal SEL. The glitch-free multiplexer 330 includes two D-type flip-flops 332 and 334 and some logic gates. The D-type flip flops 332 and 334 are respectively clocked by delayed versions of clock signals S_oscP and S_oscN. The D-type flip-flop 332 receives an inverted version of the selection signal SEL as its input, whereas the D-type flip-flop 334 directly receives the selection signal SEL as its input. An output of the D-type flip-flop 332 is sent to an AND gate 336, and the AND gate 336 performs an AND operation upon the output and the delayed version of the clock signal S_oscP. An output of the D-type flip-flop 334 is sent to an AND gate 338, and the AND gate 338 performs an AND operation upon the output of the D-type flip-flop 334 and the delayed version of the clock signal S_oscN. Outputs of the AND gates 336 and 338 are further sent to an OR gate 339, thereby generating a selection result of the clock signal S_oscN and S_oscP based on an OR operation performed by the OR gate 339. The glitch-free multiplexer 330 can serve as the multiplexer 230 of FIG. 3, to guarantee a glitch-free input signal S_in for the frequency divider 210. Please note that a delay time of the D-type flip-flops 332 and 334 must be less than half a period of the clock signals S_oscP and S_oscN; otherwise, the glitch-free multiplexer 330 cannot properly provide the clock signals S_oscP and S_oscN to the frequency divider 210. Further details regarding how the signals inside the glitch-free multiplexer 330 changes are illustrated in FIG. 5B.

Compared to architecture of a traditional multiplexer, the glitch-free multiplexer 330 of the present invention saves two AND gates that are conventionally disposed before the input of the D-type flip-flops. Hence, the glitch-free multiplexer 330 both improves circuit response time and reduces the circuit area.

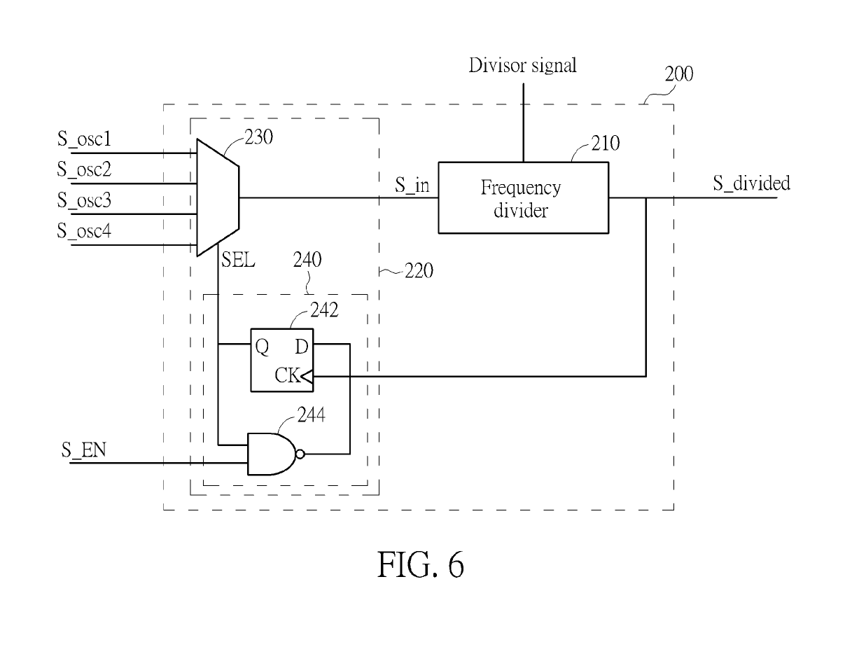

Please note that, in the above exemplary embodiments, the phase difference between clock signals S_oscP and S_oscN is described as 180 degrees, and therefore the divisor of the frequency division device 200 is adjustable in steps of 0.5. However, according to various embodiments of the present invention, the divisor of the frequency division device 200 will be adjustable in other fractional steps (e.g. 0.1, 0.2, and 0.4). FIG. 6 illustrates an embodiment where the divisor of the frequency division device 200 can be adjustable in fractional steps of 0.25 other than 0.5.

In the embodiment shown by FIG. 6, clock signals S_osc1-S_osc4 having same frequency but at different phases are provided to multiplexer 230. Enabling the divisor of the frequency division device 200 adjustable in fractional steps of 0.25 is implemented by having the clock signals S_osc1-S_osc4 at 0, 90, 180, 270 degrees, respectively. When the integer frequency division is intended, the selection signal SEL is fixed to select one of the clock signals S_osc1-S_osc4, and the frequency division device 200 functions as an integer frequency divider. When the divide-by-X.25 frequency division is intended (where the “X” is the integer divisor of the frequency divider 210), the selection signal SEL alternately selects the clock signals S_osc1-S_osc4 to be provided to the frequency divider 210. That is, the selection signal in turn selects (upon rising or falling edges of the divider output S_divided) the clock signal at 0 degree, the clock signal at 90 degree, the clock signal at 180 degree, and the clock signal at 270 degree, and then repeats, to achieve the divide-by-X.25 frequency division. Similarly, when divide-by-X.5 frequency division is intended, the selection signal SEL alternately selects the clock signals at 0 degree and 180 degree to be provided to the frequency divider 210. That is, the selection signal in turn selects (upon rising or falling edges of the divider output S_divided) the clock signal at 0 degree, and the clock signal at 180 degree, and then repeats, to achieve the divide-by-X.5 frequency division. Similarly, when divide-by-X.75 frequency division is intended, the selection signal SEL alternately selects the clock signals at S_osc1-S_osc4 to be provided to the frequency divider 210. That is, the selection signal in turn selects (upon rising or falling edges of the divider output S_divided) the clock signal at 0 degree, the clock signal at 270 degree, the clock signal at 180 degree and the clock signal at 90 degree, and then repeats, to achieve the divide-by-X.75 frequency division. In view of this, if having more clock signals at different phases is provided to the frequency division device 200, the divisor of the frequency division device 200 can be adjustable in more tiny fractional steps. For example, if N-phase clock signals are provided to the frequency division device 200, the divisor of the frequency division device 200 can be adjustable in 1/N.

In one exemplary embodiment, the clock signals S_oscP and S_oscN or S_osc1-S_osc4 are generated by one or more oscillators having differential outputs, and the clock signals S_oscP and S_oscN or S_osc1-S_osc4 are respectively provided by oscillator outputs. In another embodiments, the clock signals S_oscP and S_oscN or S_osc1-S₁₃ osc4 are generated by an oscillator having a single-ended output, wherein one of the clock signals S_oscP and S_oscN or S_osc1-S_osc4 is provided by the single-ended output, while the others are provided by an inverter or a phase shifting device subsequent to the single-ended output.

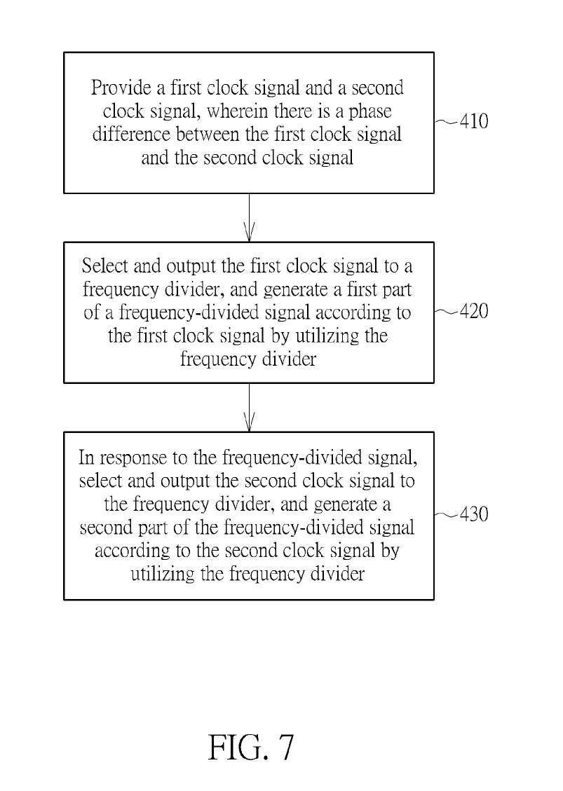

According to one exemplary embodiment of the present invention, a frequency synthesis method is provided. FIG. 7 illustrates a flowchart of the frequency synthesizing method of the present invention. The method includes the following steps:

Step 410: providing a first clock signal and a second clock signal, wherein there is a phase difference between the first clock signal and the second clock signal;

Step 420: selecting and outputting the first clock signal to the frequency divider, and generating a first part of a frequency-divided signal according to the first clock signal by utilizing the frequency divider;

Step 430: in response to the frequency-divided signal, selecting and outputting the second clock signal to the frequency divider, and generating a second part of the frequency-divided signal according to the second clock signal by utilizing the frequency divider.

In step 410, the first clock signal and a second clock signal is provided. As mentioned above, if the phase difference between the first clock signal and the second clock signal is 180 degrees, the first and second clock signals could be generated from an oscillator having differential outputs, or an oscillator having a single-ended output with an additional inverter inverting the single-ended output. Furthermore, if the phase difference is not 180 degrees, the first clock signal and the second clock signal could be generated with an oscillator and a phase shifting circuit for providing the phase difference.

In step 420, the first clock signal is selected and output to the frequency divider to generate the first part of the frequency-divided signal. As mentioned above, the frequency divider 210 generates the rising edge R2 of the frequency-divided signal S_divided according to the rising edge R1 of the clock signal S_ocnN.

In step 430, in response to the frequency-divided signal, the second clock signal is selected and output to the frequency divider to generate the second part of the frequency-divided signal. As mentioned above, the rising edge R2 of the frequency-divided signal S_divided triggers the selection signal generation circuit 240 to change the level of the selection signal SEL, thereby allowing the multiplexer 230 to select the clock signal S_ocnP. The frequency divider 210 generates the falling edge F1 and the rising edge R7 of the frequency-divided signal S_divided according to, respectively, the rising edges R4 and R6 of the clock signal S_ocnP.

In conclusion, the present invention provides a method to reduce an output frequency range of an oscillator occupied by a wireless system in a chip, which also means the present invention allows more wireless systems to be integrated into a chip. In addition, the present invention utilizes a divisor control circuit to realize fractional frequency division based on an integer frequency divider. This solution will help to achieve better PLL performance.

Reference in the specification to “one embodiment” or “an embodiment” means that a particular feature, structure, or characteristic described in connection with the embodiment is included in at least an implementation. The appearances of the phrase “in one embodiment” in various places in the specification are not necessarily all referring to the same embodiment. Thus, although embodiments have been described in language specific to structural features and/or methodological acts, it is to be understood that claimed subject matter may not be limited to the specific features or acts described. Rather, the specific features and acts are disclosed as sample forms of implementing the claimed subject matter.

Those skilled in the art will readily observe that numerous modifications and alterations of the device and method may be made while retaining the teachings of the invention. Accordingly, the above disclosure should be construed as limited only by the metes and bounds of the appended claims.

1. A divisor control circuit for allowing a frequency divider to have a fractional divisor, comprising:
a multiplexer, arranged to select one of a first clock signal and a second clock signal as a multiplexed signal according to a selection signal, and accordingly provide the multiplexed signal to the frequency divider, wherein there is a phase difference between the first clock signal and the second clock signal; and
a selection signal generation circuit, coupled to the multiplexer, arranged to generate the selection signal according to a frequency-divided signal output by the frequency divider;
wherein the multiplexer alternately selects the first clock signal or the second clock signal as the multiplexed signal during a period of the frequency-divided signal.

2. The divisor control circuit of claim 1, wherein the selection signal generation circuit comprises:
a flip-flop, coupled to the multiplexer and the frequency divider, arranged to capture a logic signal to accordingly output the selection signal, wherein the flip-flop is clocked by the frequency-divided signal; and
a logic circuit, coupled to the flip-flop, arranged to perform a logic operation upon the selection signal and an enablement signal to generate the logic signal.

3. The divisor control circuit of claim 2, wherein the flip-flop is a D-type flip-flop and the logic circuit comprises a NAND gate.

4. The divisor control circuit of claim 1, wherein the multiplexer comprises:
a first flip-flop, arranged to capture an inverted selection signal to output a first output signal, wherein the first flip-flop is clocked by a delayed version of the first clock signal;
a second flip-flop, arranged to capture the selection signal to output a second output signal, wherein the second flip-flop is clocked by a delayed version of the second clock signal; and
a logic circuit, coupled to the first flip-flop and the second flip-flop, arranged to perform a plurality of logic operations upon the first output signal and the second output signal to generate the multiplexed signal.

5. The divisor control circuit of claim 1, wherein the first clock signal and the second clock signal have a same frequency, and the phase difference between the first clock signal and the second clock signal is 180 degrees.

6. A frequency division device, comprising:
a multiplexer, arranged to select one of a first clock signal and a second clock signal as a multiplexed signal according to a selection signal, wherein there is a phase difference between the first clock signal and the second clock signal;
a frequency divider, coupled to the multiplexer, arranged to generate a frequency-divided signal according to the multiplexed signal; and
a selection signal generation circuit, coupled to the multiplexer and the frequency divider, arranged to provide the selection signal according to the frequency-divided signal;
wherein the multiplexer alternately selects the first clock signal or the second clock signal as the multiplexed signal during a period of the frequency-divided signal.

7. The frequency division device of claim 6, wherein the selection signal generation circuit comprises:
a flip-flop, coupled to the multiplexer and the frequency divider, arranged to capture a logic signal to accordingly output the selection signal, wherein the flip-flop is clocked by the frequency-divided signal; and
a logic circuit, coupled to the flip-flop, arranged to perform a logic operation upon the selection signal and an enablement signal to generate the logic signal.

8. The frequency division device of claim 7, wherein the flip-flop is a D-type flip-flop and the logic circuit comprises a NAND gate.

9. The frequency division device of claim 6, wherein the multiplexer comprises:
a first flip-flop, arranged to capture an inverted selection signal to output a first output signal, wherein the first flip-flop is clocked by a delayed version of the first clock signal;
a second flip-flop, arranged to capture the selection signal to output a second output signal, wherein the second flip-flop is clocked by a delayed version of the second clock signal; and
a logic circuit, coupled to the first flip-flop and the second flip-flop, arranged to perform a plurality of logic operations upon the first output signal and the second output signal to generate the multiplexed signal.

10. The frequency division device of claim 6, wherein the first clock signal and the second clock signal have a same frequency, and the phase difference between the first clock signal and the second clock signal is 180 degrees.

11. The frequency division device of claim 6, wherein the frequency divider is an integer frequency divider.

12. A frequency synthesizer, comprising:
an oscillator, arranged to generate at least a first clock signal;
a multiplexer, coupled to the oscillator, arranged to select one of the first clock signal and a second clock signal as a multiplexed signal according to a selection signal, wherein there is a phase difference between the first clock signal and the second clock signal;
a frequency divider, coupled to the multiplexer, arranged to generate a frequency-divided signal according to the multiplexed signal; and
a selection signal generation circuit, coupled to the multiplexer and the frequency divider, arranged to provide the selection signal according to the frequency-divided signal;
wherein the multiplexer alternately selects the first clock signal or the second clock signal as the multiplexed signal during a period of the frequency-divided signal.

13. The frequency synthesizer of claim 12, wherein the oscillator has differential outputs, and one of the differential outputs provides the first clock signal and the other provides the second clock signal.

14. The frequency synthesizer of claim 12, wherein the oscillator has a single-ended output and the single-ended output provides the first clock signal.

15. The frequency synthesizer of claim 14, wherein the clock generation further comprises:
an inverter, coupled between the single-ended output of the oscillator and the multiplexer, arranged to invert the first clock signal to generate the second clock signal.

16. The frequency synthesizer of claim 14, wherein the clock generation further comprises:
a phase shifting device, coupled between the single-ended output of the oscillator and the multiplexer, arranged to shift a phase of the first clock signal to generate the second clock signal.

17. The frequency synthesizer of claim 12, wherein the selection signal generation circuit comprises:
a flip-flop, coupled to the multiplexer and the frequency divider, arranged to capture a logic signal to accordingly output the selection signal, wherein the flip-flop is clocked by the frequency-divided signal; and
a logic circuit, coupled to the flip-flop, arranged to perform a logic operation upon the selection signal and an enablement signal to generate the logic signal accordingly.

18. The frequency synthesizer of claim 17, wherein the flip-flop is a D-type flip-flop and the logic circuit comprises a NAND gate.

19. The frequency synthesizer of claim 12, wherein the multiplexer comprises:
a first flip-flop, arranged to capture an inverted selection signal to output a first output signal, wherein the first flip-flop is clocked by a delayed version of the first clock signal;
a second flip-flop, arranged to capture the selection signal to output a second output signal, wherein the second flip-flop is clocked by a delayed version of the second clock signal; and
a logic circuit, coupled to the first flip-flop and the second flip-flop, arranged to perform a plurality of logic operations upon the first output signal and the second output signal to generate the multiplexed signal.

20. The frequency synthesizer of claim 12, wherein the frequency divider is an integer frequency divider.

21. A frequency synthesis method, comprising:
providing a first clock signal and a second clock signal, wherein there is a phase difference between the first clock signal and the second clock signal;
selecting the first clock signal and providing the first clock signal to a frequency divider for generating a first part of a frequency-divided signal according to the first clock signal; and
in response to the frequency-divided signal, selecting the second clock signal and providing the second clock signal to the frequency divider for generating a second part of the frequency-divided signal according to the second clock signal.
